(19) United States
(12) Patent Application Publication
(10) Pub. No.: US 2026/0101736 A1
(43) Pub. Date: Apr. 9, 2026

(54) SEMICONDUCTOR PACKAGE

(71) Applicant: SAMSUNG ELECTRONICS CO., LTD., Suwon-si (KR)

(72) Inventors: Yubin SONG, Suwon-si (KR); Pilkyu KANG, Suwon-si (KR); Jaewha PARK, Suwon-si (KR)

(73) Assignee: SAMSUNG ELECTRONICS CO., LTD., Suwon-si (KR)

(21) Appl. No.: 19/082,715

(22) Filed: Mar. 18, 2025

(30) Foreign Application Priority Data
Sep. 25, 2024 (KR) 10-2024-0129752

(51) Int. Cl. H01L 23/00; H01L 23/13; H01L 23/14; H01L 23/31; H01L 23/48; H01L 25/03

(52) U.S. Cl. CPC H10W 20/20; H10W 70/68; H10W 90/00; H10W 70/698; H10W 74/111; H10W 90/792

(57) ABSTRACT

A semiconductor package may include: a first semiconductor chip including a first substrate including a first front surface opposite to a first rear surface, first front pads on the first front surface, first through-electrodes electrically connected to the first front pads, and first rear pads on the first through-electrodes, the first through-electrodes penetrating the first substrate and protruding to the first rear surface; a first step structure including a first dummy substrate, a first buffer layer on the first dummy substrate, and a first cavity penetrating the first dummy substrate and the first buffer layer, with the first semiconductor chip in the first cavity; and a first dielectric layer on at least portions of the first semiconductor chip and the first step structure, and around the first through-electrodes and the first rear pads on the first rear surface of the first substrate.

### CROSS-REFERENCE TO RELATED APPLICATION

This application claims benefit of priority to Korean Patent Application No. 10-2024-0129752 filed on Sep. 25, 2024 in the Korean Intellectual Property Office, the disclosure of which is incorporated herein by reference in its entirety.

### BACKGROUND

### 1. Field

Example embodiments of the present disclosure relate to a semiconductor package.

### 2. Description of Related Art

As electronic products are designed to have high-performance and to be miniaturized, the demand for a semiconductor package in which different types of semiconductor chips are integrated has increased. Accordingly, a technique of stacking semiconductor chips electrically connected to each other vertically, by a through silicon via (TSV) has been developed.

### SUMMARY

An example embodiment of the present disclosure is to provide a semiconductor package having improved reliability.

According to one or more example embodiments, a semiconductor package may include: a first semiconductor chip including a first substrate including a first front surface opposite to a first rear surface, first front pads on the first front surface, first through-electrodes electrically connected to the first front pads, and first rear pads on the first through-electrodes, the first through-electrodes penetrating the first substrate and protruding to the first rear surface; a first step structure including a first dummy substrate, a first buffer layer on the first dummy substrate, and a first cavity penetrating the first dummy substrate and the first buffer layer, with the first semiconductor chip in the first cavity; a first dielectric layer on at least portions of the first semiconductor chip and the first step structure, and around the first through-electrodes and the first rear pads on the first rear surface of the first substrate; a top semiconductor chip on the first dielectric layer and including connection pads electrically connected to the first rear pads; and bump structures below the first semiconductor chip and connected to the first front pads. The first step structure may have a first surface of the first dummy substrate facing in a same direction as the first front surface of the first substrate, and a second surface of the first buffer layer facing in a same direction as the first rear surface of the first substrate, and a first distance between the first rear surface of the first substrate and an uppermost surface of the first dielectric layer may be greater than a second distance between the second surface of the first step structure and the uppermost surface of the first dielectric layer.

According to one or more example embodiments, a semiconductor package may include: a semiconductor chip including a substrate including a front surface opposite to a rear surface, front pads on the front surface, through-electrodes electrically connected to the front pads, and rear pads on the through-electrodes, the through-electrodes penetrating the substrate and protruding to the rear surface; a step structure including a dummy substrate, a buffer layer on the dummy substrate, and a cavity penetrating the dummy substrate and the buffer layer, with the semiconductor chip in the cavity; and a dielectric layer on at least portions of the semiconductor chip and the step structure, and around the through-electrodes and the rear pads on the rear surface of the substrate. The substrate and the dummy substrate may include a first material, and the buffer layer may include a second material different from the first material.

According to one or more example embodiments, a semiconductor package may include: a semiconductor chip including a substrate including a front surface opposite to a rear surface, front pads on the front surface, through-electrodes electrically connected to the front pads, and rear pads on the through-electrodes, the through-electrodes penetrating the substrate and protruding to the rear surface; a step structure around the semiconductor chip and including a lower surface opposite to an upper surface; a gap-fill dielectric layer on the rear surface of the semiconductor chip, and the upper surface of the step structure; a bonding dielectric layer on the gap-fill dielectric layer and on at least portions of the rear pads; and a top semiconductor chip on the semiconductor chip, and including connection pads in contact with the rear pads, and a bonding insulating layer on at least portions of the connection pads and in contact with the bonding dielectric layer. An upper surface of the gap-fill dielectric layer and upper ends of the through-electrodes may provide a flat surface with the bonding dielectric layer and the rear pads on the flat surface, and the step structure may include a buffer layer adjacent to the flat surface.

### BRIEF DESCRIPTION OF THE DRAWINGS

The above and other aspects, features, and advantages of the present disclosure will be more clearly understood from the following detailed description, taken in combination with the accompanying drawings, in which:

FIG. 1A is a cross-sectional diagram illustrating a semiconductor package according to one or more embodiments of the present disclosure, viewed from the side;

FIG. 1B is a cross-sectional diagram taken along line I-I′ in FIG. 1A according to one or more embodiments;

FIG. 2 is a cross-sectional diagram illustrating a semiconductor package according to one or more embodiments of the present disclosure, viewed from the side;

FIG. 3A is a diagram illustrating a process of manufacturing the semiconductor package illustrated in FIG. 1A according to one or more embodiments;

FIG. 3B is a diagram illustrating a process of manufacturing the semiconductor package illustrated in FIG. 1A according to one or more embodiments;

FIG. 3C is a diagram illustrating a process of manufacturing the semiconductor package illustrated in FIG. 1A according to one or more embodiments;

FIG. 3D is a diagram illustrating a process of manufacturing the semiconductor package illustrated in FIG. 1A according to one or more embodiments;

FIG. 3E is a diagram illustrating a process of manufacturing the semiconductor package illustrated in FIG. 1A according to one or more embodiments;

FIG. 3F is a diagram illustrating a process of manufacturing the semiconductor package illustrated in FIG. 1A according to one or more embodiments;

FIG. 3G is a diagram illustrating a process of manufacturing the semiconductor package illustrated in FIG. 1A according to one or more embodiments;

FIG. 3H is a diagram illustrating a process of manufacturing the semiconductor package illustrated in FIG. 1A according to one or more embodiments;

FIG. 3I is a diagram illustrating a process of manufacturing the semiconductor package illustrated in FIG. 1A according to one or more embodiments;

FIG. 3J is a diagram illustrating a process of manufacturing the semiconductor package illustrated in FIG. 1A according to one or more embodiments;

FIG. 3K is a diagram illustrating a process of manufacturing the semiconductor package illustrated in FIG. 1A according to one or more embodiments;

FIG. 4 is a cross-sectional diagram illustrating a semiconductor package according to one or more embodiments of the present disclosure, viewed from the side;

FIG. 5A is a diagram illustrating a process of manufacturing the semiconductor package illustrated in FIG. 4 according to one or more embodiments;

FIG. 5B is a diagram illustrating a process of manufacturing the semiconductor package illustrated in FIG. 4 according to one or more embodiments;

FIG. 5C is a diagram illustrating a process of manufacturing the semiconductor package illustrated in FIG. 4 according to one or more embodiments;

FIG. 5D is a diagram illustrating a process of manufacturing the semiconductor package illustrated in FIG. 4 according to one or more embodiments;

FIG. 6 is a cross-sectional diagram illustrating a semiconductor package according to one or more embodiments of the present disclosure, viewed from the side;

FIG. 7A is a diagram illustrating a process of manufacturing the semiconductor package illustrated in FIG. 6 according to one or more embodiments;

FIG. 7B is a diagram illustrating a process of manufacturing the semiconductor package illustrated in FIG. 6 according to one or more embodiments;

FIG. 7C is a diagram illustrating a process of manufacturing the semiconductor package illustrated in FIG. 6 according to one or more embodiments;

FIG. 8 is a cross-sectional diagram illustrating a semiconductor package according to one or more embodiments of the present disclosure, viewed from the side;

FIG. 9A is a diagram illustrating a process of manufacturing the semiconductor package illustrated in FIG. 8 according to one or more embodiments;

FIG. 9B is a diagram illustrating a process of manufacturing the semiconductor package illustrated in FIG. 8 according to one or more embodiments;

FIG. 9C is a diagram illustrating a process of manufacturing the semiconductor package illustrated in FIG. 8 according to one or more embodiments;

FIG. 10 is a cross-sectional diagram illustrating a semiconductor package according to one or more embodiments of the present disclosure, viewed from the side;

FIG. 11A is a diagram illustrating a process of manufacturing the semiconductor package illustrated in FIG. 10 according to one or more embodiments;

FIG. 11B is a diagram illustrating a process of manufacturing the semiconductor package illustrated in FIG. 10 according to one or more embodiments; and

FIG. 11C is a diagram illustrating a process of manufacturing the semiconductor package illustrated in FIG. 10 according to one or more embodiments.

### DETAILED DESCRIPTION

Hereinafter, embodiments of the present disclosure will be described as follows with reference to the accompanying drawings.

In the disclosure, spatially relative terms such as “top”, “bottom”, “upper”, “lower”, “up”, “down”, “horizontal,” “vertical,” “higher,” “lower,” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

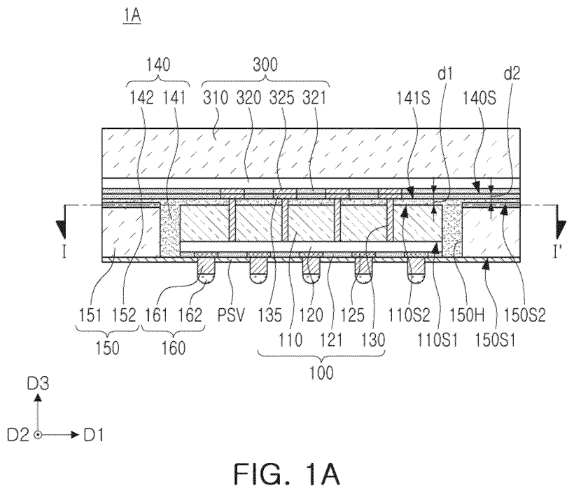

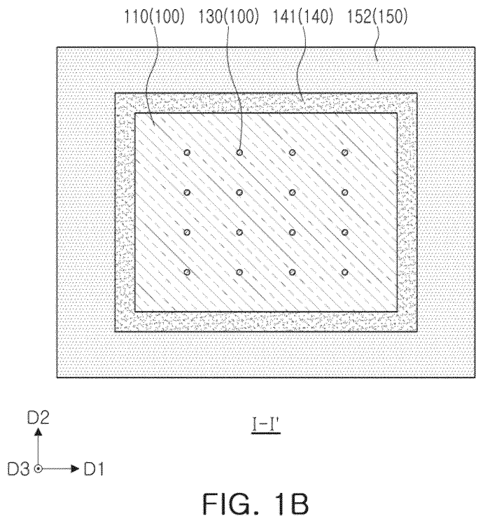

FIG. 1A is a cross-sectional diagram illustrating a semiconductor package according to one or more embodiments. FIG. 1B is a cross-sectional diagram taken along line I-I′ in FIG. 1A.

Referring to FIGS. 1A and 1B, a semiconductor package 1A in one or more embodiments may include a semiconductor chip 100, a dielectric layer 140, and a step structure 150. In one or more embodiments, the semiconductor package 1A may further include a top semiconductor chip 300.

The semiconductor chip 100 may include a logic chip, such as a central processor (CPU), a graphics processor (GPU), a field programmable gate array (FPGA), an application processor (AP), a digital signal processor (DSP), a cryptographic processor, a microprocessor, a microcontroller, an analog-to-digital converter, an application-specific IC (ASIC), and a memory chip, such as a volatile memory such as a dynamic RAM (DRAM) and a static RAM (SRAM), and a nonvolatile memory such as a phase change RAM (PRAM), a magnetic RAM (MRAM), a resistive RAM (RRAM), and a flash memory. The semiconductor chip 100 may be provided as two or more semiconductor chips adjacent to each other in the horizontal directions D1 and D2.

The semiconductor chip 100 may include a substrate 110, a circuit layer 120, a bonding insulating layer 121, front pads 125, through-electrodes 130, and rear pads 135. The semiconductor chip 100 may be configured as a bare-state semiconductor chip in which no separate bumps or interconnections are formed. In one or more embodiments, the semiconductor chip 100 may be configured as a packaged type semiconductor chip.

The substrate 110 may have a front surface 110S1 and a rear surface 110S2 opposite to each other. The substrate 110 may be a semiconductor wafer including a semiconductor element such as silicon, germanium, or a compound semiconductor such as silicon carbide (SiC), gallium arsenide (GaAs), indium arsenide (InAs), and indium phosphide (InP). A front surface 110S1 of the substrate 110 may be a surface on which an active region doped with impurities is formed (e.g., a surface facing the circuit layer 120), and a rear surface 110S2 of the substrate 110 may be a surface on which an active region is not formed.

The circuit layer 120 may be disposed on the front surface 110S1 of the substrate 110. The circuit layer 120 may include an integrated circuit including individual elements formed on the front surface 110S1 of the substrate 110, and an interconnection structure electrically connecting the individual elements to front pads 125. The “individual elements” may include various active elements and/or passive elements such as field effect transistor (FET) elements such as planar FET or FinFET, memory elements such as a flash memory, DRAM, SRAM, EEPROM, PRAM, MRAM, FeRAM, RRAM, logic elements such as AND, OR, NOT, and system LSI, CIS, MEMS. The “interconnection structure” may be formed as a multilayer structure including interconnection patterns and vias formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. The circuit layer 120 may further include an interlayer insulating layer covering the “individual elements” and the “interconnection structure.” The “interlayer insulating layer” may include flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or a combination thereof.

The front pads 125 may be connection terminals electrically connected to an integrated circuit of the circuit layer 120. The front pads 125 may include one of copper (Cu), nickel (Ni), titanium (Ti), aluminum (Al), gold (Au), and silver (Ag), or an alloy thereof. The front pads 125 may be connection terminals of a bare chip (e.g., aluminum pads), but an example embodiment thereof is not limited thereto. in one or more embodiments, the front pads 125 may be connection structures formed on the connection terminals of the bare chip (e.g., copper pads). A barrier layer including at least one of titanium (Ti), titanium nitride (TiN), tantalum (Ta), and tantalum nitride (TaN) may be formed between the front pads 125 and the bonding insulating layer 121.

A bonding insulating layer 121 (also referred to as an “insulating layer”) may be disposed below the circuit layer 120 and may surround the front pads 125. The bonding insulating layer 121 may include, for example, at least one of silicon oxide (SiO), silicon nitride (SiN), and silicon carbonitride (SiCN).

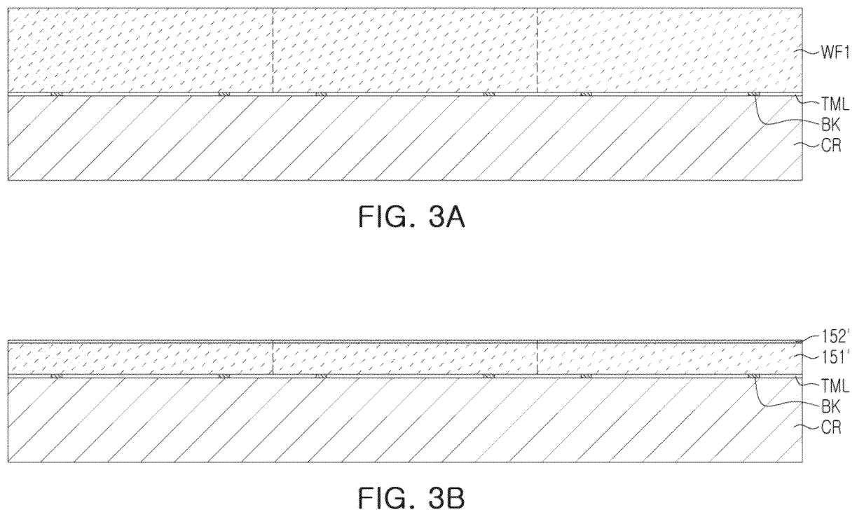

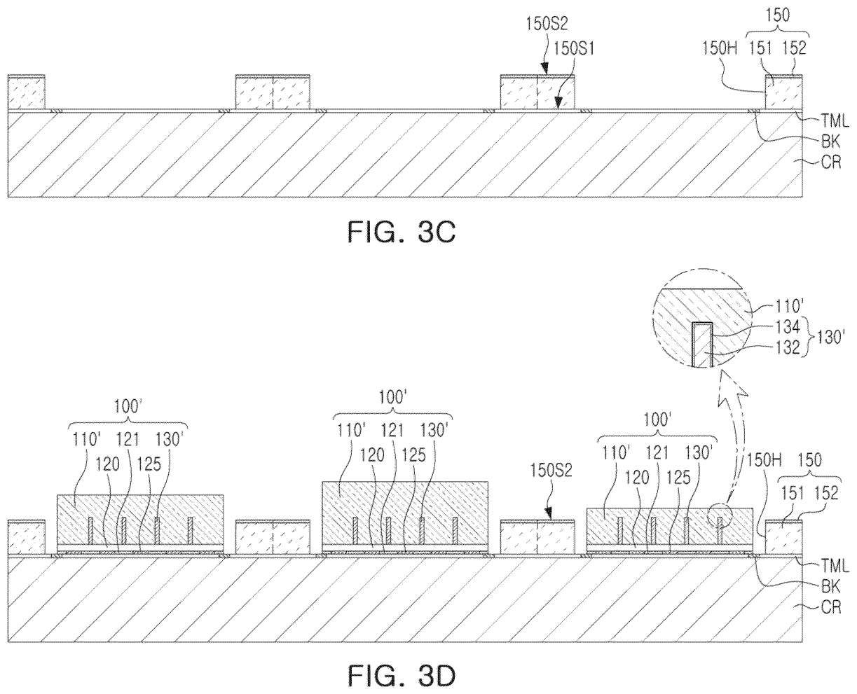

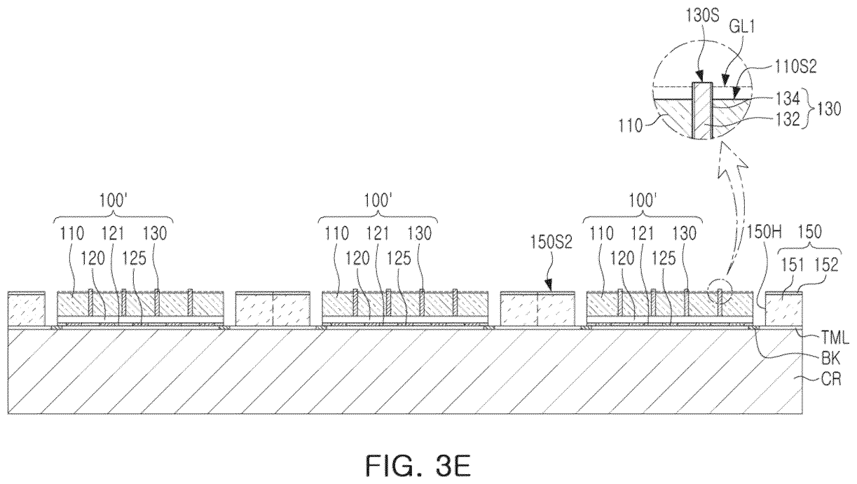

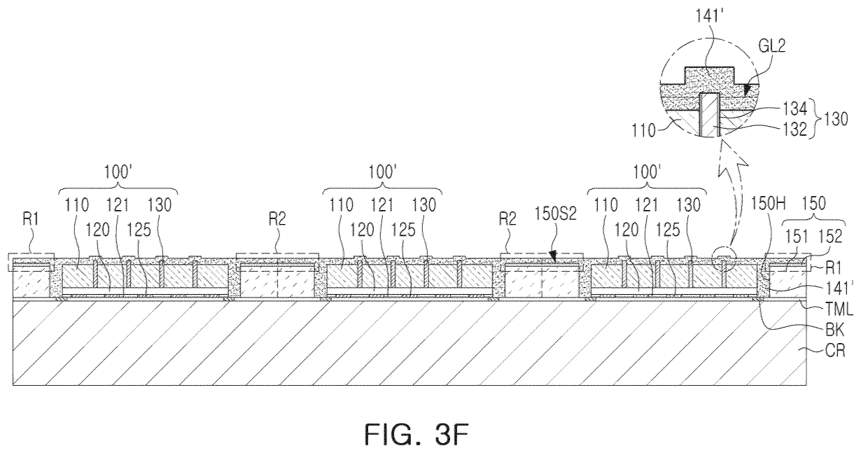

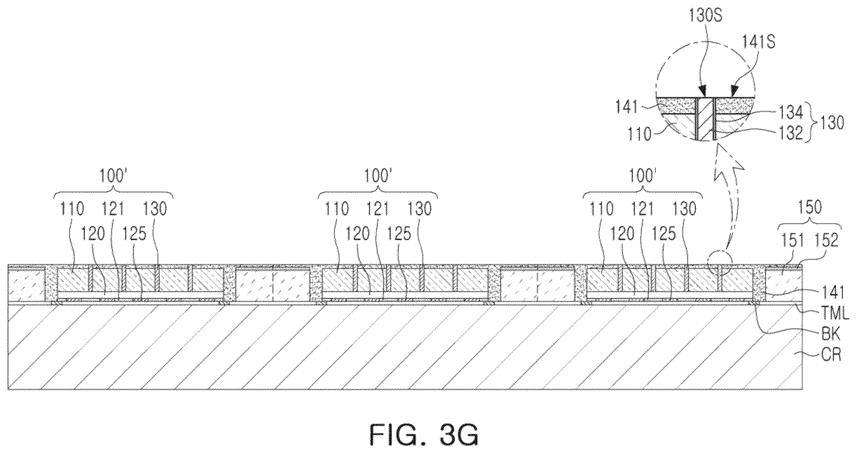

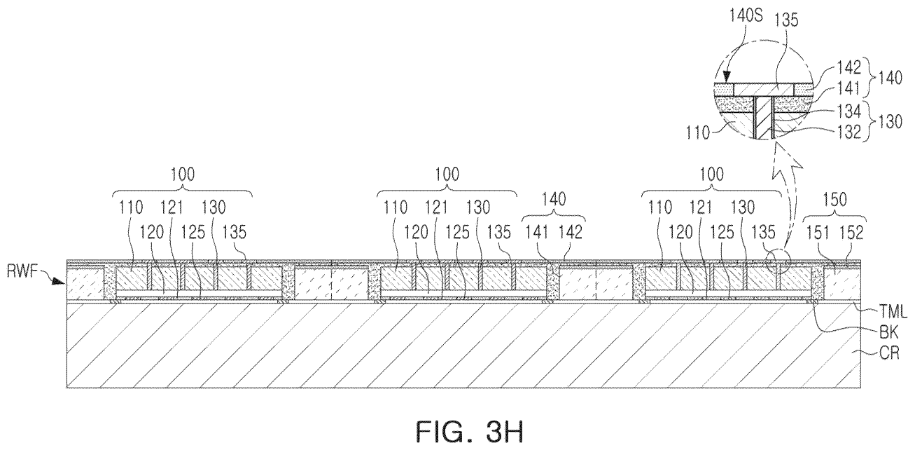

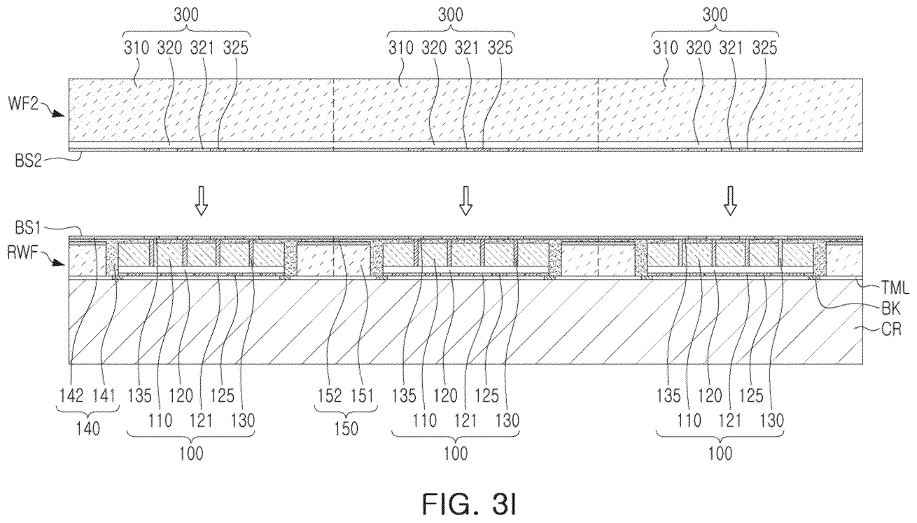

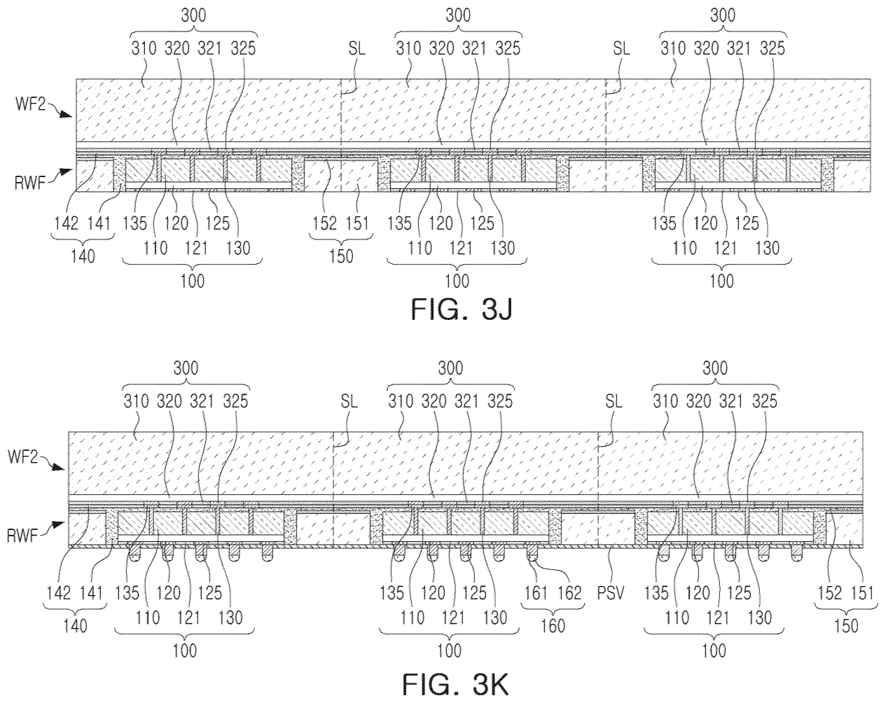

Through-electrodes 130 may electrically connect the front pads 125 to the rear pads 135. The through-electrodes 130 may be electrically connected to the front pads 125 and may extend to the rear surface 110S2 of the substrate 110. The through-electrodes 130 may penetrate the substrate 110 and may protrude to a rear surface 110S2. An upper end of the through-electrodes 130 in contact with the rear pads 135 may be at the same level as or higher than a level of the second surface 150S2 of the step structure 150 (see FIG. 3G).

The rear pads 135 may be disposed on each of the through-electrodes 130. The rear pads 135 may include one of copper (Cu), nickel (Ni), titanium (Ti), aluminum (Al), gold (Au), silver (Ag), or an alloy thereof. The rear pads 135 may be spaced apart from the substrate 110. A dielectric layer 140 may be filled between the rear pads 135 and the rear surface 110S2 of the substrate 110.

The bump structures 160 may be disposed below the semiconductor chip 100. The bump structures 160 may be electrically connected to the front pads 125 of the semiconductor chip 100. The bump structures 160 may connect the semiconductor package 1A to an external device, such as a module substrate, or a main board. For example, the bump structures 160 may include a pillar portion 161 and a solder portion 162. The pillar portion 161 may include copper (Cu) or an alloy of copper (Cu), and the solder portion 162 may include a low melting point metal, such as tin (Sn) or an alloy including tin (Sn) (e.g., Sn—Ag, or Sn—Ag—Cu). In one or more embodiments, the bump structures 160 may include only the pillar portion 161 or only the solder portion 162.

The dielectric layer 140 may cover at least a portion of each of the semiconductor chip 100 and the step structure 150, and may surround a side surface of the through-electrodes 130 and a side surface of the rear pads 135 on the rear surface 110S2 of the substrate 110. The dielectric layer 140 may include at least one of silicon oxide (SiO), silicon nitride (SiN), and silicon carbonitride (SiCN). The dielectric layer 140 may include a gap-fill dielectric layer 141 and a bonding dielectric layer 142. The gap-fill dielectric layer 141 and the bonding dielectric layer 142 may include the same material (e.g., silicon oxide), but an example embodiment thereof is not limited thereto.

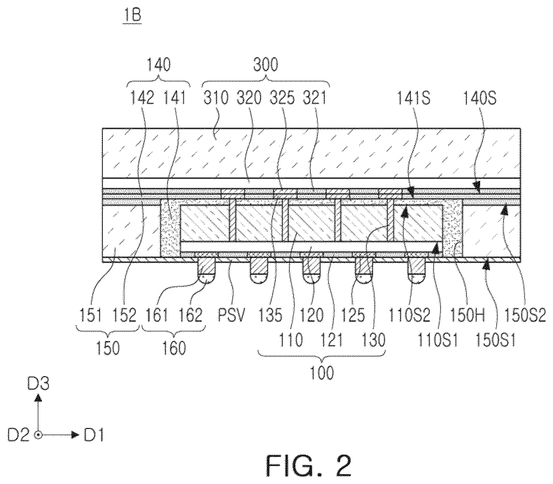

The gap-fill dielectric layer 141 may cover the rear surface 110S2 and the side surface of the substrate 110, one portion (referring to a portion protruding to the rear surface 110S2) of a side surface of each of the through-electrodes 130, and a side surface and an upper surface (or referred to as the ‘second surface’) 150S2 of the step structure 150. In one or more embodiments, the upper surface 150S2 of the step structure 150 may be exposed from the gap-fill dielectric layer 141 (the example embodiment in FIG. 2). A lower surface of the gap-fill dielectric layer 141 may be coplanar with a lower surface (or referred to as the “first surface”) 150S1 of the step structure 150. The gap-fill dielectric layer 141 may fill a space between the step structure 150 and the semiconductor chip 100, and may include at least one of silicon oxide (SiO) and silicon nitride (SiN) applied to protect the through-electrodes 130 during a planarization process (e.g., a CMP process).

The bonding dielectric layer 142 may be disposed on the upper surface 141S of the gap-fill dielectric layer 141 and may cover a side surface of each of the rear pads 135. The bonding dielectric layer 142 may provide a bonding surface for bonding and coupling to the top semiconductor chip 300. The bonding dielectric layer 142 may include a material which may be bonded and coupled to the bonding insulating layer 221 of the top semiconductor chip 300, for example, silicon oxide (SiO) or silicon carbonitride (SiCN). The materials for forming the dielectric layer 140 are not limited to the examples described above. Depending on processes, a boundary between the bonding dielectric layer 142 and the bonding insulating layer 221 may not be distinct.

According to one or more embodiments, by including a step structure 150 disposed around the semiconductor chip 100 and complementing a step difference corresponding to the thickness of the semiconductor chip 100, flatness of the bonding surface (the uppermost surface 140S of the dielectric layer 140) provided by (of) the bonding dielectric layer 142 may be improved, and accordingly, bonding quality between the top semiconductor chip 300 and the dielectric layer 140 and reliability of the semiconductor package 1A may be improved.

The step structure 150 may be disposed around the semiconductor chip 100. The step structure 150 may include a dummy substrate 151 and a buffer layer 152. The step structure 150 may penetrate the dummy substrate 151 and the buffer layer 152, and may include a cavity 150H in which the semiconductor chip 100 is accommodated.

The dummy substrate 151 may provide a lower surface or a first surface 150S1 of the step structure 150 facing in the same direction as the front surface 110S1 of the substrate 110. The dummy substrate 151 may include a first material the same as or similar to the substrate 110 of the semiconductor chip 100. The dummy substrate 151 may include a semiconductor material such as a semiconductor element such as silicon, germanium, or a compound semiconductor such as SiC, GaAs, InAs, and InP. For example, the dummy substrate 151 may include silicon (Si) or a silicon compound.

The buffer layer 152 may provide an upper surface or a second surface 150S2 facing in the same direction as the rear surface 110S2 of the substrate 110. The buffer layer 152 may be disposed on a dummy substrate 151. The buffer layer 152 may work as a stop line for a leveling process while a reconfigured wafer is manufactured. The buffer layer 152 may be adjacent to a flat surface provided by (of) the upper surface 141S of the gap-fill dielectric layer 141 and an upper end (“130S” in FIG. 3G) of each of the through-electrodes 130. A distance between the buffer layer 152 and the flat surface may be smaller than a distance between the substrate 110 and the flat surface. For example, a first distance d1 between the rear surface 110S2 of the substrate 110 and the uppermost surface 140S of the dielectric layer 140 may be greater than a second distance d2 between the second surface 150S2 of the step structure 150 and the uppermost surface 140S of the dielectric layer 140.

The buffer layer 152 may include a material which may be used as a stopper in a process of grinding the substrate 110 and a process of polishing the dielectric layer 140. The buffer layer 152 may include a second material different from a first material of the dummy substrate 151. The buffer layer 152 may include at least one of oxide and nitride of a semiconductor material. For example, the buffer layer 152 may include at least one of silicon oxide (SiO), silicon nitride (SiN), and silicon oxynitride (SiON).

The top semiconductor chip 300 may be disposed on the semiconductor chip 100. The top semiconductor chip 300 may be a bare-state semiconductor chip without bumps or interconnections formed therein. In one or more embodiments, the top semiconductor chip 300 may be a packaged-type semiconductor chip. The top semiconductor chip 300 and the semiconductor chip 100 may be chiplets included in a multi-chip module (MCM). For example, the top semiconductor chip 300 may include a processor circuit, and the semiconductor chip 100 may include an input/output circuit, an analog circuit, a memory circuit, a serial-to-parallel conversion circuits, or the like.

The top semiconductor chip 300 may include a substrate 310, a circuit layer 320, a bonding insulating layer 321, and connection pads 325. Since the top semiconductor chip 300 may include components substantially the same as or similar to those of the semiconductor chip 100, the same or similar components are indicated by the same as or similar reference numerals, and repeated descriptions of the same or similar components hereinafter will not be provided. For example, the substrate 310, the circuit layer 320, the bonding insulating layer 321, and the connection pads 325 may be configured the same as or similar to the substrate 110, the circuit layer 120, the bonding insulating layer 121, and the front pads 125 described above, respectively.

The bonding insulating layer 321 may be formed to surround the connection pads 325. The bonding insulating layer 321 may provide a bonding surface for coupling to the bonding dielectric layer 142. The bonding insulating layer 321 may include a material which may be bonded and coupled to the bonding dielectric layer 142, for example, silicon oxide (SiO) or silicon carbonitride (SiCN).

The connection pads 325 may be connection terminals electrically connected to an integrated circuit of the circuit layer 220. The connection pads 325 may be coupled to the rear pads 135 of the semiconductor chip 100. The connection pads 325 may include a material which may be bonded and coupled to the rear pads 135, for example, copper (Cu). The connection pads 325 may be a bonding structure formed on the connection terminals (e.g., aluminum pads) of the bare chip.

In one or more embodiments, the semiconductor package 1A may further include a passivation layer PSV. The passivation layer PSV may be formed to surround each of the bump structures 160 below the semiconductor chip 100. The passivation layer PSV may protect the front pads 125 and the bump structures 160 from external physical/chemical damages. The passivation layer PSV may include at least one of silicon oxide (SiO) and silicon nitride (SiN), but an example embodiment thereof is not limited thereto. The passivation layer PSV may also include a material such as photosensitive polyimide (PSPI), for example.

FIG. 2 is a cross-sectional diagram illustrating a semiconductor package according to one or more embodiments.

Referring to FIG. 2, a semiconductor package 1B in one or more embodiments may be configured the same as or similar to the example described with reference to FIGS. 1A and 1B, other than the configuration in which the step structure 150 is in contact with the bonding dielectric layer 142. At least a portion of the bonding dielectric layer 142 may be in contact with the second surface 150S2 of the step structure 150. An upper end of the through-electrodes 130, an upper surface 141S of the gap-fill dielectric layer 141, and a second surface 150S2 of the step structure 150 may be substantially coplanar with each other. The structure in the example embodiment may be formed by polishing the upper surface 141S of the gap-fill dielectric layer 141 until the buffer layer 152 of the step structure 150 is exposed in the process of polishing the gap-fill dielectric layer 141 described later with reference to FIGS. 3F and 3G.

FIGS. 3A to 3K are diagrams illustrating a process of manufacturing the semiconductor package illustrated in FIG. 1A.

Referring to FIG. 3A, a first semiconductor wafer WF1 may be attached to a reconfigured carrier CR on which a temporary bonding layer TML and bonding keys BK are formed. The reconfigured carrier CR may be a wafer substrate, such as a 6-inch, 8-inch, or 12-inch wafer, including dozens or more of units (e.g., three) illustrated in the diagram. The temporary bonding layer TML may include silicon oxide (SiO). The temporary bonding layer TML may be formed using a deposition process (e.g., a CVD process). The bonding key BK may be an alignment key for determining an attachment position of the semiconductor chip 100 in a subsequent process. The first semiconductor wafer WF1 may be a silicon (Si) wafer to which a back-grinding process for adjusting a thickness is not applied.

Referring to FIG. 3B, a preliminary substrate 151′ and a preliminary buffer layer 152′ may be formed. The preliminary substrate 151′ may be a first semiconductor wafer WF1 of which a thickness is reduced by a grinding process. The preliminary substrate 151′ may be, for example, a silicon (Si) substrate. The preliminary buffer layer 152′ may be formed using a CVD process. The preliminary buffer layer 152′ may include a material which may be used as a stopper in a subsequent process. The preliminary buffer layer 152′ may be, for example, a silicon nitride (SiN) thin film.

Referring to FIG. 3C, a step structure 150 may be formed. The step structure 150 may include a dummy substrate 151, a buffer layer 152, and cavities 150H. The dummy substrate 151 and the buffer layer 152 may be the preliminary substrate 151′ and the preliminary buffer layer 152′ etched to form the cavities 150H, respectively. The cavities 150H may be formed by partially etching the preliminary substrate 151′ and the preliminary buffer layer 152′. The cavities 150H may penetrate the dummy substrate 151 and the buffer layer 152 in the vertical direction. The cavities 150H may be formed with a width for exposing the bonding keys BK.

Referring to FIG. 3D, the preliminary semiconductor chips 100′ may be attached to the temporary bonding layer TML. For bonding of the preliminary semiconductor chips 100′, a surface of the temporary bonding layer TML exposed to the cavities 150H may be cleaned using a descum process. The preliminary semiconductor chips 100′ may be KGDs (known good die) having completed testing. The preliminary semiconductor chips 100′ may be attached at a position determined using the bonding key BK as an alignment key. The preliminary semiconductor chips 100′ may be attached to a temporary bonding layer TML by a thermal compression process. The thermal compression process may be performed in a thermal atmosphere ranging from about 100° C. to about 300° C. A temperature of the thermal atmosphere is not limited to the above-mentioned range and may be varied. A boundary between the bonding insulating layer 121 and the temporary bonding layer TML may not be distinct.

The preliminary semiconductor chips 100′ may include a preliminary substrate 110′, a circuit layer 120, preliminary through-electrodes 130′, front pads 125, and a bonding insulating layer 121. The preliminary semiconductor chips 100′ may be chips diced from a single wafer of which a thickness is controlled by a back-grinding process. In one or more embodiments, the chips may be integrated circuit chips diced from different wafers. The preliminary semiconductor chips 100′ may have a total thickness variation resulting from the wafer back-grinding process. For example, each of the preliminary semiconductor chips 100′ may include preliminary substrates 110′ having different thicknesses.

The preliminary through-electrodes 130′ may include a via plug 132 and a side barrier film 134. The via plug 132 may extend in the vertical direction in the preliminary substrate 110′. The via plug 132 may include, for example, tungsten (W), titanium (Ti), aluminum (Al), or copper (Cu) and may be formed by a plating process, a PVD process, or a CVD process. The side barrier film 134 may extend along a surface of the via plug 132. The side barrier film 134 may include, for example, titanium (Ti), titanium nitride (TiN), tantalum (Ta), or tantalum nitride (TaN) and may be formed by a plating process, a PVD process, or a CVD process. In one or more embodiments, the preliminary through-electrodes 130′ may further include a side insulating film. The side insulating film may be disposed between the side barrier film 134 and the preliminary substrate 110′. The side insulating film may include an insulating material (e.g., high aspect ratio process (HARP) oxide) such as silicon oxide, silicon nitride, and silicon oxynitride.

Referring to FIG. 3E, through-electrodes 130 may protrude to a rear surface 110S2 of the substrate 110. The substrate 110 may be formed by removing an upper portion of the preliminary substrate 110′. For example, the preliminary substrate 110′ may be ground to a first level GL1 using a grinding process, and thereafter, the rear surface 110S2 to which the through-electrodes 130 protrude may be formed using an etch-back process. The buffer layer 152 of the step structure 150 may be used as a stopper for the grinding process. The first level GL1 may be understood as a reference line in contact with the second surface 150S2 of the step structure 150. The through-electrodes 130 may be formed by removing preliminary through-electrodes 130′ by a grinding process. The preliminary through-electrodes 130′ may include a material having higher resistance against the grinding process than the preliminary substrate 110′. Accordingly, the upper end 130S of the through-electrodes 130 may be positioned at a level the same as or higher than the first level GL1.

Referring to FIG. 3F, a gap-fill material layer 141′ may be formed. The gap-fill material layer 141′ may be formed to cover the step structure 150 and the preliminary semiconductor chip 100′. The gap-fill material layer 141′ may conformally extend along surfaces of the step structure 150, the substrate 110, and the through-electrodes 130. The gap-fill material layer 141′ may include, for example, silicon oxide (SiO) and may be formed using a CVD process. According to one or more embodiments, by including the step structure 150, a step difference of the gap-fill material layer 141′ in a gap region R2 between an edge region R1 of a reconfigured carrier CR and the preliminary semiconductor chips 100′ may be improved. Accordingly, filling properties of the gap-fill material layer 141′ around the preliminary semiconductor chips 100′ and efficiency of a subsequent process of polishing the gap-fill material layer 141′ may be improved. In a subsequent process, a flat surface from which the gap-fill material layer 141′ and the through-electrodes 130 are removed to a second level GL2 may be formed. The second level GL2 may be positioned at a level than higher a level of the second surface 150S2 of the step structure 150. In one or more embodiments, the second level GL2 may be positioned at the same level as the second surface 150S2 of the step structure 150 (the example embodiment in FIG. 2).

Referring to FIG. 3G, a gap-fill dielectric layer 141 may be formed. The gap-fill dielectric layer 141 may be formed by applying a CMP process to the gap-fill material layer 141′. The gap-fill material layer 141′ may be polished such that the upper end 130S of the through-electrodes 130 is exposed. The upper surface 141S of the gap-fill dielectric layer 141 and the upper end 130S of the through-electrodes 130 may be coplanar with each other. The gap-fill dielectric layer 141 may surround a side surface of each of the through-electrodes 130 protruding from the rear surface 110S2 of the substrate 110.

Referring to FIG. 3H, rear pads 135 and a bonding dielectric layer 142 may be formed. The bonding dielectric layer 142 may include silicon oxide (SiO) and may be formed using a CVD process. The rear pads 135 may be formed in the bonding dielectric layer 142 patterned using a photosensitive material layer and a photolithography process. The rear pads 135 may include a metal such as copper (Cu) or titanium (Ti) and may be formed by a plating process. The bonding dielectric layer 142 and the rear pads 135 may be planarized by a CMP process. According to one or more embodiments, a step difference of the dielectric layer 140 may be removed by the step structure 150, and a reconfigured wafer RWF having improved bonding surface quality may be formed. The upper surface of the bonding dielectric layer 142, that is, the uppermost surface 140S of the dielectric layer 140, may provide a flat surface for wafer-to-wafer bonding described below.

Referring to FIG. 3I, a second semiconductor wafer WF2 may be attached to the reconfigured wafer RWF. The second semiconductor wafer WF2 may be a wafer having a size corresponding to the reconfigured carrier CR. The second semiconductor wafer WF2 may be a wafer on which an integrated circuit for top semiconductor chips 300 is formed. The second semiconductor wafer WF2 may include a substrate 310, a circuit layer 320, connection pads 325, and a bonding insulating layer 321. The second semiconductor wafer WF2 may be attached in a state in which a thickness of the substrate 310 is adjusted by a grinding process, or the grinding process may be applied after the reconfigured wafer RWF is attached. The reconfigured wafer RWF may include a first bonding surface BS1 provided by (of) rear pads 135 and a bonding dielectric layer 142. The second semiconductor wafer WF2 may include a second bonding surface BS2 provided by (of) connection pads 325 and a bonding insulating layer 321. The bonding insulating layer 321 of the second semiconductor wafer WF2 and the bonding dielectric layer 142 of the reconfigured wafer RWF may form dielectric-dielectric coupling by a thermal compression process. Also, the connection pads 325 of the second semiconductor wafer WF2 and the rear pads 135 of the reconfigured wafer RWF may form metal-metal coupling by a thermal compression process.

Referring to FIG. 3J, the reconfigured carrier CR and the temporary bonding layer TML may be removed. The reconfigured carrier CR and the temporary bonding layer TML may be removed by combining a grinding process and an etching process. The temporary bonding layer TML may be completely removed such that the front pads 125 and the step structure 150 of the semiconductor chip 100 may be exposed.

Referring to FIG. 3K, a passivation layer PSV and bump structures 160 may be formed. The passivation layer PSV may be formed using a deposition process or a coating process. The passivation layer PSV may be formed to cover the front pads 125 and the step structure 150. The bump structures 160 may penetrate the passivation layer PSV and may be electrically connected to the front pads 125. Thereafter, the semiconductor packages may be separated from each other along the scribe lane SL. According to one or more embodiments, a semiconductor package having improved reliability and yield may be manufactured by improving quality of the bonding interfacial surface of the reconfigured wafer RWF and the second semiconductor wafer WF2.

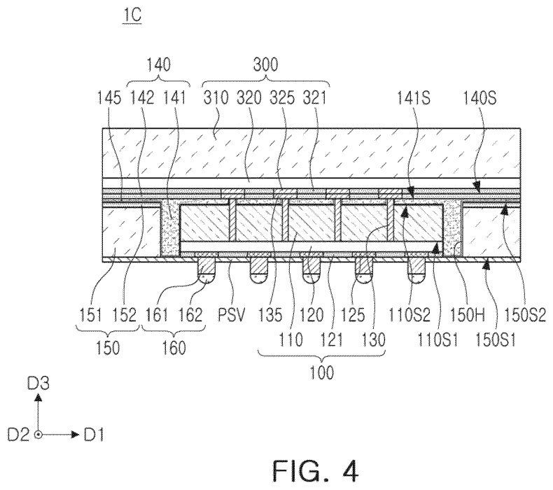

FIG. 4 is a cross-sectional diagram illustrating a semiconductor package according to one or more embodiments.

Referring to FIG. 4, a semiconductor package 1C in one or more embodiments may be configured the same as or similar to the example described with reference to FIGS. 1A to 3K, other than the configuration in which a buffer insulating layer 145 is included. The buffer insulating layer 145 may be disposed between the dielectric layer 140 and the step structure 150, and between the dielectric layer 140 and the semiconductor chip 100. The buffer insulating layer 145 may extend conformally along a surface of the step structure 150 and a surface of the semiconductor chip 100. The buffer insulating layer 145 may surround a side surface of the through-electrodes 130 protruding toward the rear surface 110S2 of the semiconductor chip 100. The buffer insulating layer 145 may include at least one of silicon oxide (SiO) and silicon nitride (SiN). In one or more embodiments, the buffer insulating layer 145 may include two or more types of thin films stacked in order. For example, the buffer insulating layer 145 may include a silicon oxide thin film in contact with a surface of the step structure 150 and a surface of the semiconductor chip 100, and a silicon nitride thin film between the silicon oxide thin film and the dielectric layer 140. The buffer insulating layer 145 may support and protect the through-electrodes 130, and may improve adhesion of the dielectric layer 140.

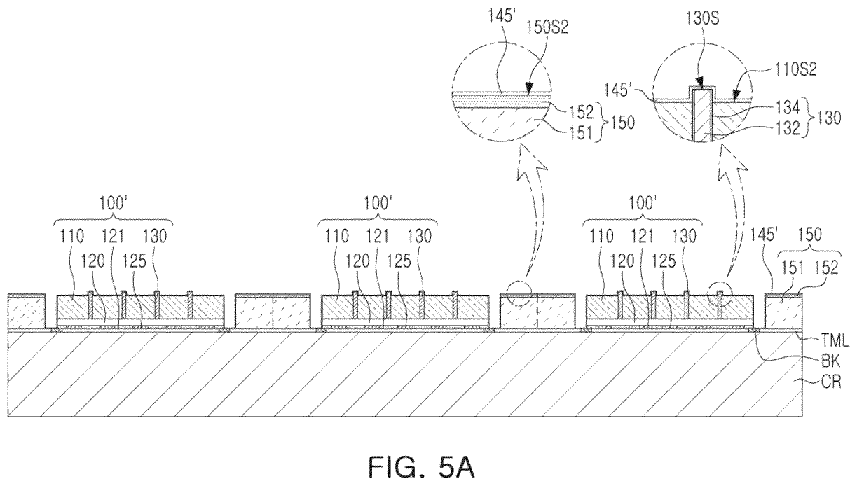

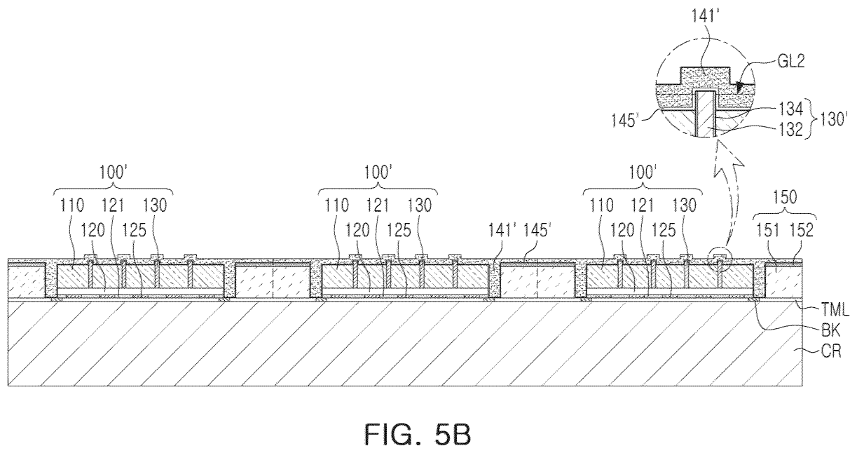

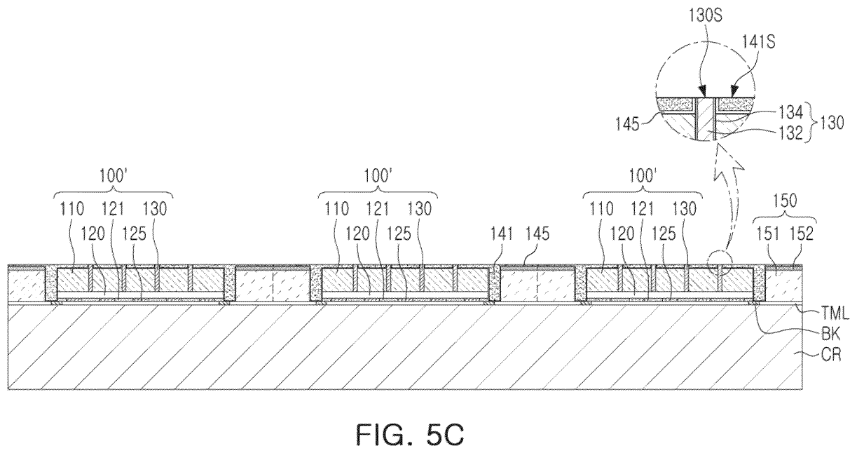

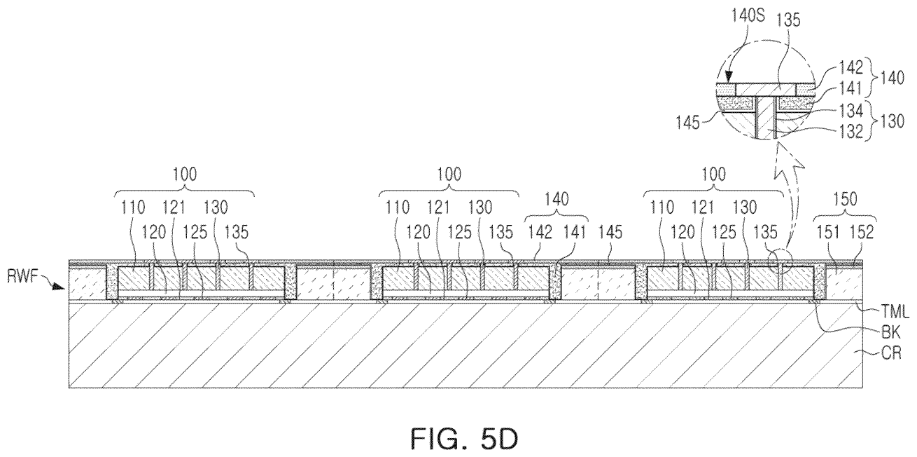

FIGS. 5A to 5D are diagrams illustrating a process of manufacturing the semiconductor package illustrated in FIG. 4. The process of manufacturing the semiconductor package 1C in FIG. 4 may be understood to be the same as or similar to the example described with reference to FIGS. 3A to 3K other than the example described below.

Referring to FIG. 5A, a buffer material layer 145′ covering the substrate 110 and the step structure 150 may be formed. The buffer material layer 145′ may conformally extend along the upper surface 150S2 of the step structure 150, the upper surface (the rear surface 110S2 of the substrate 110) of the preliminary semiconductor chip 100′, and the upper end 130S of the through-electrodes 13. The buffer material layer 145′ may include, for example, silicon oxide (SiO), silicon nitride (SiN), or the like, and may be formed using a CVD process. The buffer material layer 145′ may be formed after the through-electrodes 130 is exposed to the rear surface 110S2 of the substrate 110. The through-electrodes 130 may be exposed from the substrate 110 using a grinding process and an etch-back process (see FIG. 3E).

Referring to FIG. 5B, a gap-fill material layer 141′ may be formed on a buffer material layer 145′. The gap-fill material layer 141′ may conformally extend along a surface of the buffer material layer 145′. The gap-fill material layer 141′ may include, for example, silicon oxide (SiO), and may be formed using a CVD process. The buffer material layer 145′ may include a material having excellent adhesion to the gap-fill material layer 141′. The buffer material layer 145′ may include silicon oxide (SiO), silicon nitride (SiN), or the like. In a subsequent process, a flat surface on which the buffer material layer 145′, the gap-fill material layer 141′, and the through-electrodes 130 are removed up to the second level GL2 may be formed.

Referring to FIG. 5C, a buffer insulating layer 145 and a gap-fill dielectric layer 141 may be formed. The buffer insulating layer 145 may be formed by applying a CMP process to a buffer material layer 145′. The buffer insulating layer 145 may surround a side surface of each of through-electrodes 130 protruding to the rear surface 110S2 of the semiconductor chip 100. The gap-fill dielectric layer 141 may be formed by applying a CMP process to the gap-fill material layer 141′. The gap-fill material layer 141′ may be polished such that an upper end 130S of the through-electrodes 130 may be exposed. The upper surface 141S of the gap-fill dielectric layer 141 may be coplanar with the upper end 130S of the through-electrodes 130 and the upper end of the buffer insulating layer 145.

Referring to FIG. 5D, rear pads 135 and bonding dielectric layer 142 may be formed. The bonding dielectric layer 142 may include silicon oxide (SiO) and may be formed using a CVD process. The rear pads 135 may be formed in the bonding dielectric layer 142 patterned using a photosensitive material layer and a photolithography process. The rear pads 135 may include a metal such as copper (Cu) or titanium (Ti) and may be formed by a plating process. The bonding dielectric layer 142 and the rear pads 135 may be planarized by a CMP process. A step difference of the dielectric layer 140 may be removed by the step structure 150, and a reconfigured wafer RWF having improved bonding surface quality may be formed. Also, a reconfigured wafer RWF in which adhesion of the dielectric layer 140 is improved may be formed by the buffer insulating layer 145.

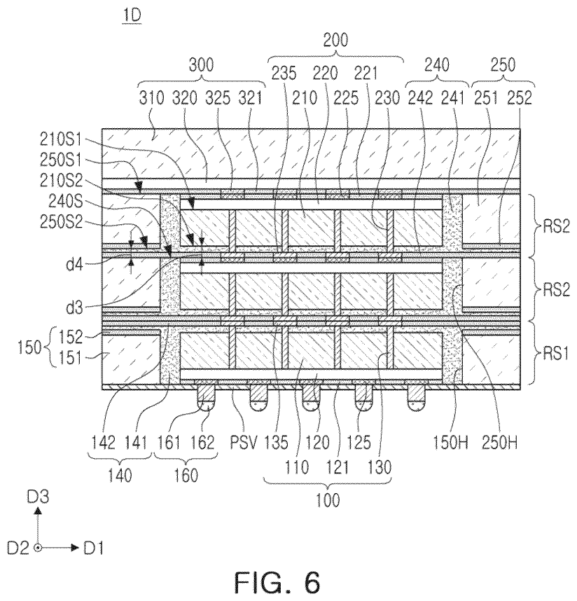

FIG. 6 is a cross-sectional diagram illustrating a semiconductor package according to one or more embodiments.

Referring to FIG. 6, a semiconductor package 1D in one or more embodiments may be configured the same as or similar to the example described with reference to FIGS. 1a to 5d, other than the configuration in which second reconfigured structures RS2 are further included. The semiconductor package 1D may include a first reconfigured structure RS1, at least one second reconfigured structure RS2, and an top semiconductor chip 300. The first reconfigured structure RS1 may be configured to include a first semiconductor chip 100, a first dielectric layer 140, and a first step structure 150 described with reference to FIGS. 1A and 1B.

The second reconfigured structure RS2 may be disposed between the first reconfigured structure RS1 and the top semiconductor chip 300. The second reconfigured structure RS2 may include a second semiconductor chip 200, a second dielectric layer 240, and a second step structure 250. Since the second reconfigured structure RS2 may have components substantially the same as or similar to those of the first reconfigured structure RS1, the same or similar components may be represented by the same as or similar reference numerals, and repeated descriptions of the same or similar components hereinafter will not be provided. For example, the second semiconductor chip 200, the second dielectric layer 240, and the second step structure 250 may be configured the same as or similar to the first semiconductor chip 100, the first dielectric layer 140, and the first step structure 150 described above, respectively. In one or more embodiments, the second semiconductor chips 200 and the top semiconductor chip 300 may be configured as volatile or nonvolatile memory chips, and the first semiconductor chip 100 may be configured as a buffer chip for the memory chips. The semiconductor package 1D may be provided as a high-performance memory device such as an high bandwidth memory (HBM), a hybrid memory cube (HMC), or the like.

The second semiconductor chip 200 may include a second substrate 210 having a second front surface 210S1 facing the top semiconductor chip 300 and a second rear surface 210S2 facing the first semiconductor chip 100, a second bonding insulating layer 221, second front pads 225, second through-electrodes 230 protruding to the second rear surface 210S2, and second rear pads 235.

The second dielectric layer 240 may cover at least a portion of each of the second semiconductor chip 200 and the second step structure 250, and may surround the second through-electrodes 230 and the second rear pads 235 on the second rear surface 210S2. The second dielectric layer 240 may include a second gap-fill dielectric layer 241 and a second bonding dielectric layer 242. The second gap-fill dielectric layer 241 and the second bonding dielectric layer 242 may include at least one of silicon oxide (SiO), silicon nitride (SiN), and silicon carbonitride (SiCN).

The second step structure 250 may be disposed around the second semiconductor chip 200. The second step structure 250 may include a second dummy substrate 251 and a second buffer layer 252. The second step structure 150 may include a second cavity 250H in which the second semiconductor chip 200 is accommodated. The second dummy substrate 251 may provide a third surface 250S1 of the second step structure 250 facing in the same direction as the second front surface 210S1. The second dummy substrate 151 may include, for example, silicon (Si) or a silicon compound. The second buffer layer 252 may provide a fourth surface 250S2 facing in the same direction as the second rear surface 210S2.

The second buffer layer 252 may work as a stop line for a leveling process during the process of manufacturing the second reconfigured structure RS2. The second buffer layer 152 may be adjacent to a flat surface provided by (of) an upper end of each of the second gap-fill dielectric layer 241 and the second through-electrodes 230. A distance between the second buffer layer 252 and the flat surface may be smaller than a distance between the second substrate 210 and the flat surface. For example, the third distance d3 between the second rear surface 210S2 of the second substrate 210 and the lowermost surface 240S of the second dielectric layer 240 may be greater than a fourth distance d4 between the fourth surface 250S2 of the second step structure 250 and the lowermost surface 240S of the second dielectric layer 240. The second buffer layer 252 may include a material which may be used as a stopper in a grinding process and a polishing process. The second buffer layer 252 may include, for example, at least one of silicon oxide (SiO), silicon nitride (SiN), and silicon oxynitride (SiON).

The second reconfigured structure RS2 may be directly bonded to the top semiconductor chip 300 and the first reconfigured structure RS1. The second bonding dielectric layer 242 may provide a bonding surface for coupling to the first bonding dielectric layer 142 of the first reconfigured structure RS1. The second bonding dielectric layer 242 may include a material which may be bonded and coupled to the first bonding dielectric layer 142, for example, silicon oxide (SiO) or silicon carbonitride (SiCN). The second rear pads 235 may include a material which may be bonded and coupled to the first rear pads 135 of the first reconfigured structure RS1, for example, copper (Cu).

The second bonding insulating layer 221 may provide a bonding surface for coupling to the bonding insulating layer 321 of the top semiconductor chip 300. The second bonding insulating layer 221 may include a material which may be bonded and coupled to the bonding insulating layer 321 of the top semiconductor chip 300, for example, silicon oxide (SiO) or silicon carbon nitride (SiCN). The second front pads 225 may include a material which may be bonded and coupled to the connection pads 325 of the top semiconductor chip 300, for example, copper (Cu).

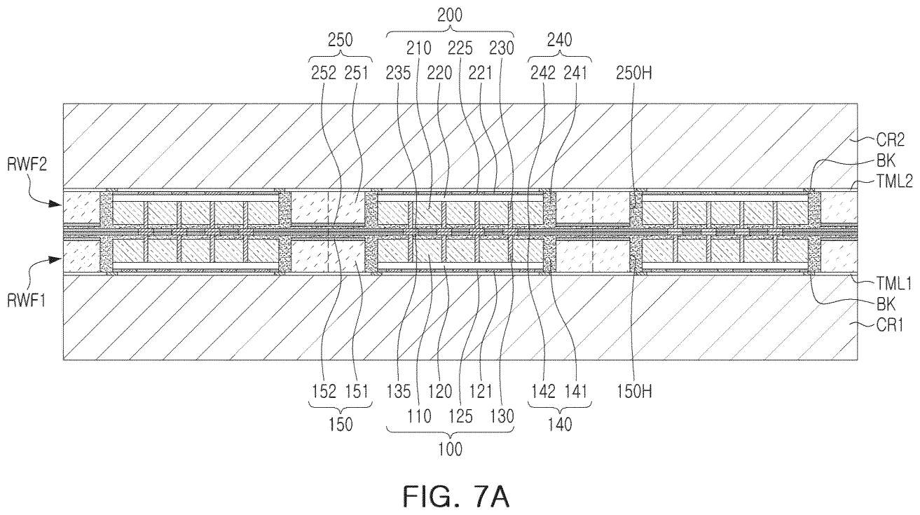

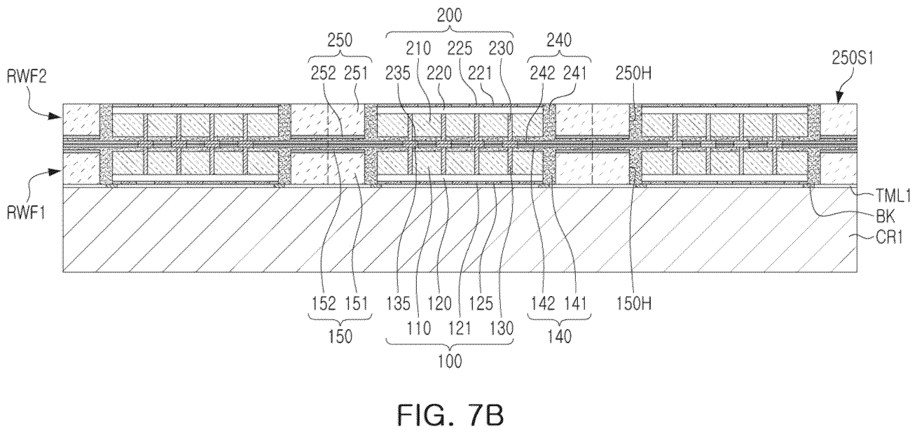

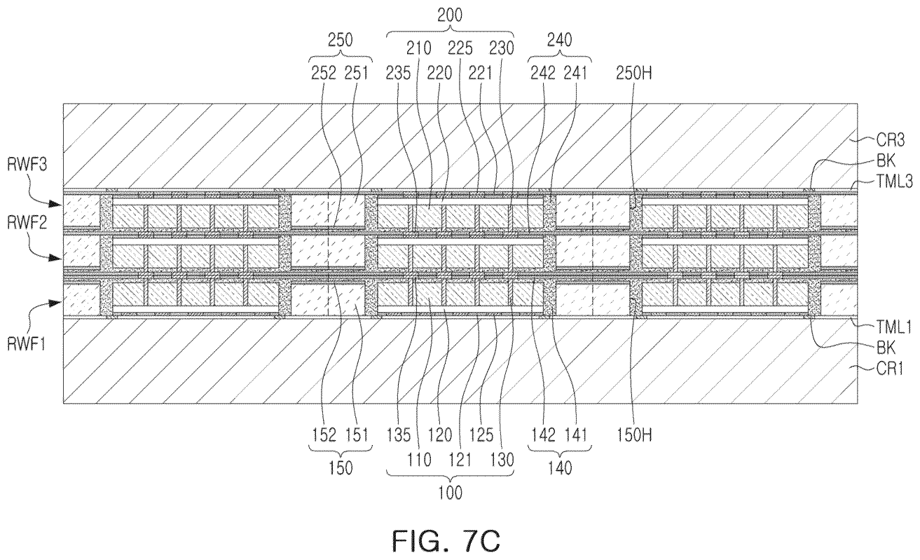

FIGS. 7A to 7C are diagrams illustrating a process of manufacturing the semiconductor package illustrated in FIG. 6. The process of manufacturing a semiconductor package 1D in FIG. 6 may be understood to be the same as or similar to the example described with reference to FIGS. 3A to 3K, other than the example described below.

Referring to FIG. 7A, a first reconfigured wafer RWF1 and a second reconfigured wafer RWF2 may be attached. The first reconfigured wafer RWF1 may be formed on the first reconfigured carrier CR1 and the first temporary bonding layer TML1. The first reconfigured wafer RWF1 may have a flat bonding surface from which a step difference is removed by the first step structure 150. The second reconfigured wafer RWF2 may be formed on the second reconfigured carrier CR2 and the second temporary bonding layer TML2. The second reconfigured wafer RWF2 may have a flat bonding surface from which a step difference is removed by the second step structure 250. The first reconfigured wafer RWF1 and the second reconfigured wafer RWF2 may be formed through the manufacturing processes in FIGS. 3A to 3H, respectively.

The first reconfigured wafer RWF1 and the second reconfigured wafer RWF2 may be directly bonded to each other by a thermocompression process. The second bonding dielectric layer 242 of the second reconfigured wafer RWF2 and the first bonding dielectric layer 142 of the first reconfigured wafer RWF1 may form dielectric-dielectric coupling. Also, the second rear pads 235 of the second reconfigured wafer RWF2 and the second rear pads 135 of the first reconfigured wafer RWF1 may form metal-metal coupling.

Referring to FIG. 7B, the second reconfigured carrier CR2 and the second temporary bonding layer TML2 may be removed. The second reconfigured carrier CR2 and the second temporary bonding layer TML2 may be removed by combining a grinding process with an etching process. The second temporary bonding layer TML2 may be completely removed to expose the second front pads 225 and the second step structure 250.

Referring to FIG. 7C, a third reconfigured wafer RWF3 may be attached to the second reconfigured wafer RWF2. The third reconfigured wafer RWF3 may be formed on the third reconfigured carrier CR3 and the third temporary bonding layer TML3. The third reconfigured wafer RWF3 may be understood to include components the same as or similar to those of the second reconfigured wafer RWF2. Thereafter, a plurality of reconfigured wafers RS1 and RS2 may be cut along the scribe lane SL, and a semiconductor package including the plurality of reconfigured structures RS1 and RS2 may be manufactured (see FIG. 6).

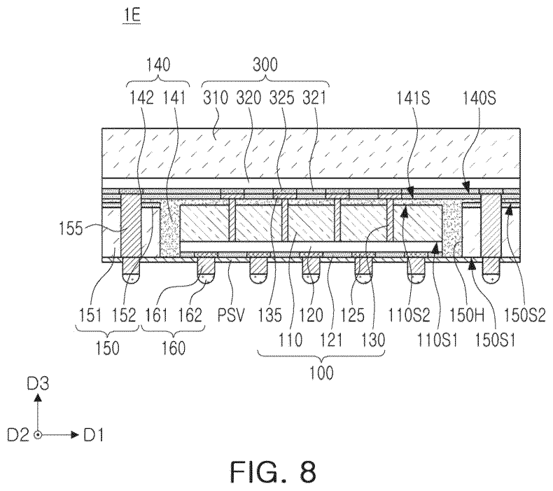

FIG. 8 is a cross-sectional diagram illustrating a semiconductor package according to one or more embodiments.

Referring to FIG. 8, a semiconductor package 1E in one or more embodiments may be configured the same as or similar to the example described with reference to FIGS. 1A to 7C, other than the configuration in which conductive posts 155 may be further included. The conductive posts 155 may electrically connect connection pads 325 of an top semiconductor chip 300 to bump structures 160. The conductive posts 155 may connect the top semiconductor chip 300 to an external device, such as a module substrate, a main board, or the like. The conductive posts 155 may penetrate the step structure 150 in the vertical direction D3. The conductive posts 155 may include, for example, one of copper (Cu), nickel (Ni), titanium (Ti), aluminum (Al), gold (Au), silver (Ag), or an alloy thereof.

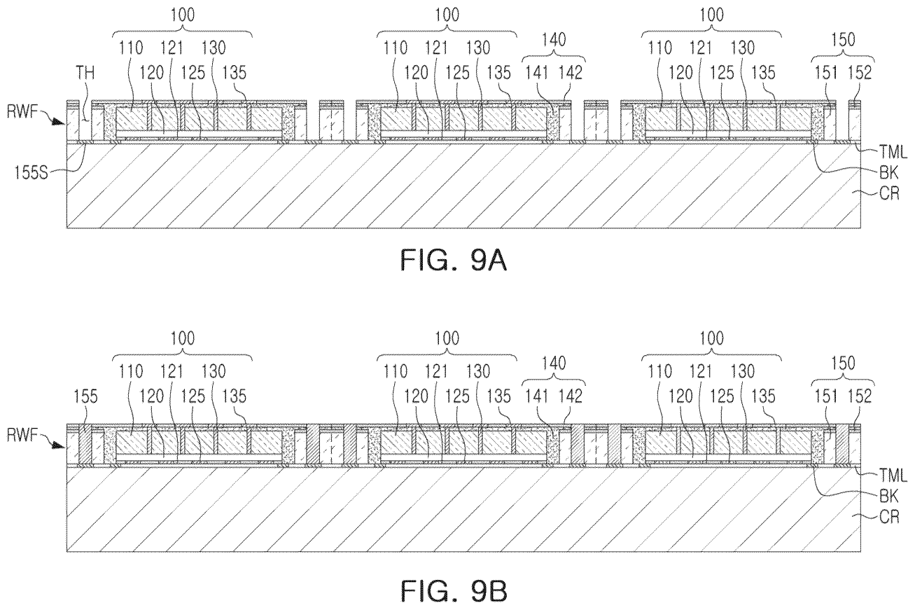

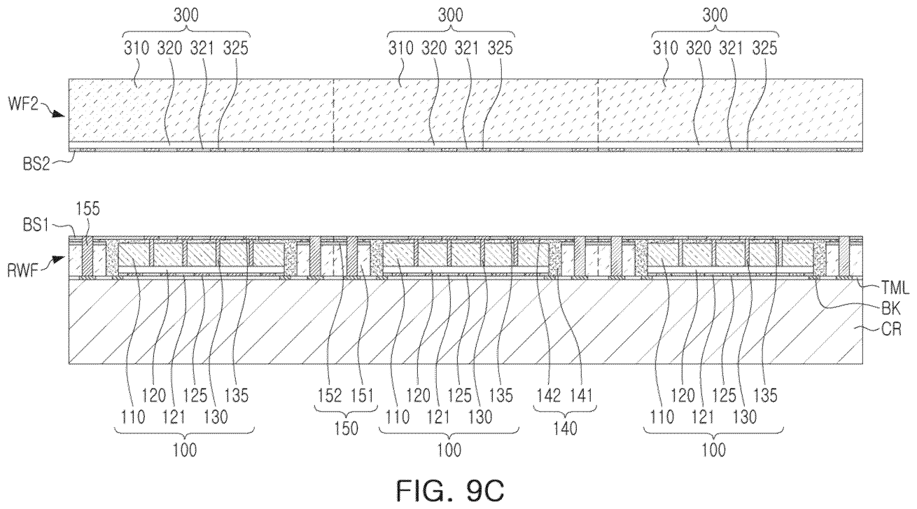

FIGS. 9A to 9C are diagrams illustrating a process of manufacturing the semiconductor package illustrated in FIG. 8. The process of manufacturing the semiconductor package 1E in FIG. 8 may be understood to be the same as or similar to the example described with reference to FIGS. 3A to 3K other than the example described below.

Referring to FIG. 9A, through-holes TH penetrating the reconfigured wafer WF may be formed. The through-holes TH may be formed by partially etching the step structure 150. The through-holes TH may be formed to expose at least a portion of the plating seed layer 155S. The reconfigured wafer WF may be formed through the manufacturing processes in FIGS. 3A to 3H.

Referring to FIG. 9B, conductive posts 155 may be formed. The conductive posts 155 may be formed by performing an electroplating process using the plating seed layer 155S. The conductive posts 155 may include copper (Cu). The conductive posts 155 may have a cylindrical shape, but an example embodiment thereof is not limited thereto. The conductive posts 155 may be processed to form a bonding surface together with the bonding dielectric layer 142 and the rear pads 135.

Referring to FIG. 9C, a second semiconductor wafer WF2 may be attached. The second semiconductor wafer WF2 may be a wafer on which an integrated circuit for top semiconductor chips 300 is formed. The reconfigured wafer RWF may include a first bonding surface BS1 provided by (of) the conductive posts 155, the rear pads 135, and the bonding dielectric layer 142. The second semiconductor wafer WF2 may include a second bonding surface BS2 provided by (of) the connection pads 325 and the bonding insulating layer 321. The connection pads 325 of the second semiconductor wafer WF2 and the rear pads 135 and the conductive posts 155 of the reconfigured wafer RWF may form metal-metal coupling by a thermal compression process.

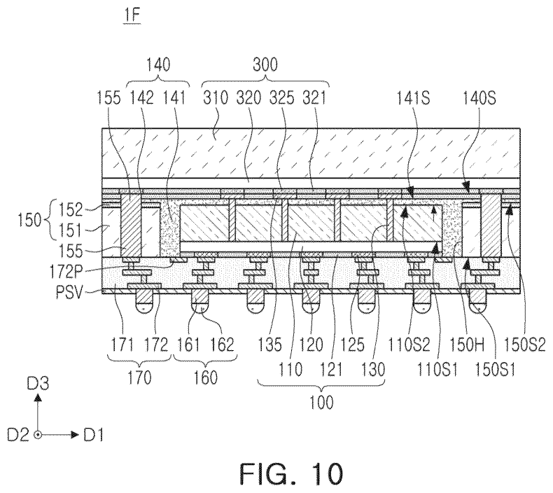

FIG. 10 is a cross-sectional diagram illustrating a semiconductor package according to one or more embodiments.

Referring to FIG. 10, a semiconductor package 1F in one or more embodiments may be configured the same as or similar to the example described with reference to FIGS. 1a to 9c, other than the configuration in which a redistribution structure 170 is further included. The redistribution structure 170 may be disposed between the semiconductor chip 100 and the bump structures 160. The redistribution structure 170 may include an insulating material layer 171 and redistribution patterns 172. Since the front pads 125 are redistributed by the redistribution structure 170, a layout of the bump structures 160 may be designed in various manners. The insulating material layer 171 may include silicon oxide. The insulating material layer 171 may be stacked as a plurality of layers depending on the number of layers of the redistribution patterns 172. A boundary between the insulating material layers 171 may not be distinct.

Redistribution patterns 172 may electrically connect the front pads 125 and the conductive posts 155 to the bump structures 160. The redistribution patterns 172 may include, for example, copper (Cu), aluminum (Al), silver (Ag), tin (Sn), gold (Au), nickel (Ni), lead (Pb), titanium (Ti), or alloys thereof. The redistribution patterns 172 may include a ground pattern, a power pattern, and a signal pattern. The signal patterns may provide transmission paths for data signals transferred from the semiconductor chip 100 and the top semiconductor chip 300, and data signals transferred from an external entity. In one or more embodiments, the redistribution patterns 172 may include a key pattern 172P used as an alignment key of the semiconductor chip 100. The redistribution patterns 172 may be formed in more or fewer layers than the example (three layers) illustrated in the diagram. The redistribution patterns 172 may be connected to each other in the vertical direction D3 by redistribution vias.

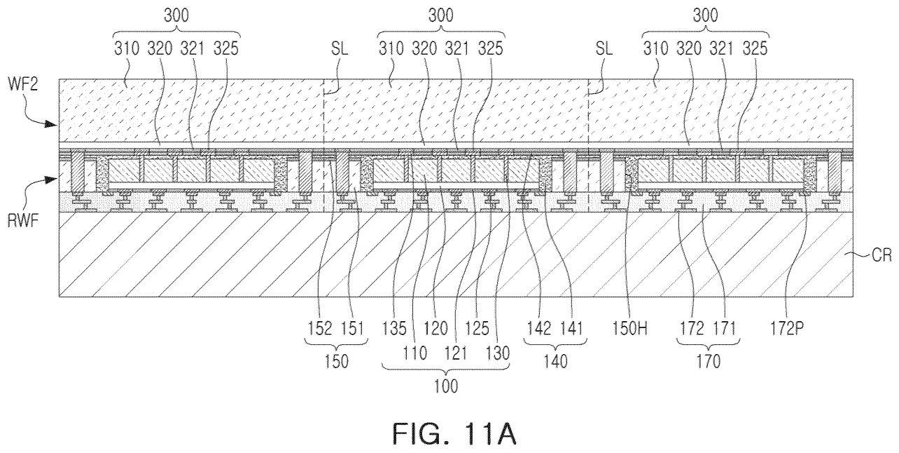

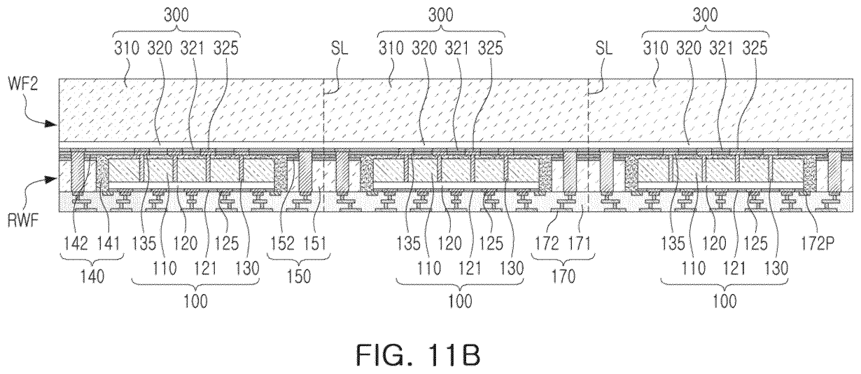

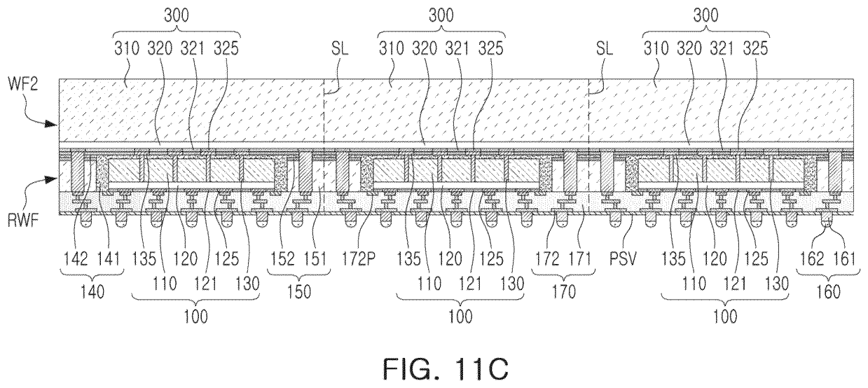

FIGS. 11A to 11C are diagrams illustrating a process of manufacturing the semiconductor package 1F illustrated in FIG. 10. The process of manufacturing a semiconductor package 1F in FIG. 10 may be understood to be the same as or similar to the example described with reference to FIGS. 3A to 3K other than the example described below.

Referring to FIG. 11A, a redistribution structure 170 may be formed on one surface of a reconfigured carrier CR. The redistribution structure 170 may include an insulating material layer 171 and redistribution patterns 172. The insulating material layer 171 may be formed using a deposition process (e.g., CVD process). The insulating material layer 171 may form dielectric-dielectric bonding with the bonding insulating layer 121 of the reconfigured wafer RWF. The key pattern 172P of the redistribution structure 170 may be used as an alignment key to determine an attachment position of the semiconductor chip 100. The reconfigured wafer WF may be formed through the manufacturing process in FIGS. 3A to 3H. A second semiconductor wafer WF2 may be attached to the reconfigured wafer RWF.

Referring to FIG. 11B, the reconfigured carrier CR may be removed. The reconfigured carrier CR may be removed by combining a grinding process with an etching process. The reconfigured carrier CR may be removed such that the redistribution patterns 172 of the redistribution structure 170 may be exposed.

Referring to FIG. 11C, a passivation layer PSV and bump structures 160 may be formed below the redistribution structure 170. The passivation layer PSV may be formed using a deposition process or a coating process. The passivation layer PSV may be formed to cover the redistribution patterns 172. The bump structures 160 may penetrate the passivation layer PSV and may be electrically connected to the redistribution patterns 172. Thereafter, the semiconductor packages may be separated along the scribe lane SL.

According to the aforementioned example embodiments, by including a step structure, a semiconductor package having improved reliability may be provided.

While the example embodiments have been illustrated and described above, it will be configured as apparent to those skilled in the art that modifications and variations could be made without departing from the scope of the present disclosure as defined by the appended claims.

What is claimed is:

1. A semiconductor package, comprising:
a first semiconductor chip comprising a first substrate comprising a first front surface opposite to a first rear surface, first front pads on the first front surface, first through-electrodes electrically connected to the first front pads, and first rear pads on the first through-electrodes, the first through-electrodes penetrating the first substrate and protruding to the first rear surface;
a first step structure comprising a first dummy substrate, a first buffer layer on the first dummy substrate, and a first cavity penetrating the first dummy substrate and the first buffer layer, with the first semiconductor chip in the first cavity;
a first dielectric layer on at least portions of the first semiconductor chip and the first step structure, and around the first through-electrodes and the first rear pads on the first rear surface of the first substrate;
a top semiconductor chip on the first dielectric layer and comprising connection pads electrically connected to the first rear pads; and
bump structures below the first semiconductor chip and connected to the first front pads,
wherein the first step structure has a first surface of the first dummy substrate facing in a same direction as the first front surface of the first substrate, and a second surface of the first buffer layer facing in a same direction as the first rear surface of the first substrate, and
wherein a first distance between the first rear surface of the first substrate and an uppermost surface of the first dielectric layer is greater than a second distance between the second surface of the first step structure and the uppermost surface of the first dielectric layer.

2. The semiconductor package of claim 1,
wherein the first substrate of the first semiconductor chip, and the first dummy substrate of the first step structure comprise a first material, and
wherein the first buffer layer of the first step structure comprises a second material different from the first material.

3. The semiconductor package of claim 2,
wherein the first material comprises silicon (Si) or a silicon compound, and
wherein the second material comprises at least one of silicon oxide (SiO), silicon nitride (SiN), or silicon oxynitride (SiON).

4. The semiconductor package of claim 1, wherein an upper end of the first through-electrodes in contact with the first rear pads is at a same level as or higher than a level of the second surface of the first step structure.

5. The semiconductor package of claim 1, wherein the first dielectric layer comprises a first gap-fill dielectric layer in contact with a side surface of the first semiconductor chip and side surfaces of the first through-electrodes, and a first bonding dielectric layer on the first gap-fill dielectric layer and in contact with side surfaces of the first rear pads.

6. The semiconductor package of claim 5,
wherein the top semiconductor chip further comprises a bonding insulating layer in contact with the first bonding dielectric layer, the bonding insulating layer being around the connection pads, and
wherein the first bonding dielectric layer and the bonding insulating layer comprise at least one of silicon oxide (SiO), or silicon carbon nitride (SiCN).

7. The semiconductor package of claim 5, wherein at least a portion of the first bonding dielectric layer is in contact with the second surface of the first step structure.

8. The semiconductor package of claim 1, further comprising:
a buffer insulating layer between the first dielectric layer and the first step structure, and between the first dielectric layer and the first semiconductor chip.

9. The semiconductor package of claim 8, wherein the buffer insulating layer comprises at least one of silicon oxide (SiO) or silicon nitride (SiN).

10. The semiconductor package of claim 1, further comprising:
at least one reconfigured structure between the first semiconductor chip and the top semiconductor chip,
wherein the at least one reconfigured structure comprises:
a second semiconductor chip comprising a second substrate comprising a second front surface facing the top semiconductor chip and a second rear surface facing the first semiconductor chip, second front pads on the second front surface, second through-electrodes electrically connected to the second front pads, and second rear pads on the second through-electrodes, the second through-electrodes penetrating the second substrate and protruding to the second rear surface,
a second step structure comprising a second dummy substrate, a second buffer layer on the second dummy substrate, and a second cavity penetrating the second dummy substrate and the second buffer layer, with the second semiconductor chip in the second cavity, and
a second dielectric layer on at least portions of the second semiconductor chip and the second step structure and around the second through-electrodes and the second rear pads on the second rear surface of the second substrate.

11. The semiconductor package of claim 10,
wherein the second step structure has a third surface of the second dummy substrate facing in a same direction as the second front surface of the second, and a fourth surface of the second buffer layer facing in a same direction as the second rear surface of the second substrate, and
wherein a third distance between the second rear surface of the second substrate and a lowermost surface of the second dielectric layer is greater than a fourth distance between the fourth surface of the second step structure and a lowermost surface of the second dielectric layer.

12. The semiconductor package of claim 10,
wherein the second front pads are in contact with the connection pads of the top semiconductor chip, and
wherein the second rear pads are in contact with the first rear pads of the first semiconductor chip.

13. The semiconductor package of claim 10,
wherein the second semiconductor chip further comprises an insulating layer around the second front pads,
wherein the top semiconductor chip further comprises a bonding insulating layer around the connection pads and in contact with the insulating layer of the second semiconductor chip, and
wherein the insulating layer and the bonding insulating layer comprise at least one of silicon oxide (SiO), or silicon carbon nitride (SiCN).

14. The semiconductor package of claim 10,
wherein the first dielectric layer comprises a first bonding dielectric layer around side surfaces of the first rear pads, and
wherein the second dielectric layer comprises a second gap-fill dielectric layer in contact with side surfaces of the second semiconductor chip and the second through-electrodes, and a second bonding dielectric layer on the second gap-fill dielectric layer and in contact with side surfaces of the second rear pads.

15. The semiconductor package of claim 14,
wherein the first bonding dielectric layer is in contact with the second bonding dielectric layer, and
wherein the first bonding dielectric layer and the second bonding dielectric layer comprise at least one of silicon oxide (SiO), or silicon carbon nitride (SiCN).

16. The semiconductor package of claim 1, further comprising:
conductive posts penetrating the first step structure and connecting the connection pads of the top semiconductor chip to the bump structures.

17. The semiconductor package of claim 1, further comprising:
a redistribution structure between the first semiconductor chip and the bump structures, and comprising redistribution patterns electrically connecting the first front pads to the bump structures.

18. A semiconductor package, comprising:
a semiconductor chip comprising a substrate comprising a front surface opposite to a rear surface, front pads on the front surface, through-electrodes electrically connected to the front pads, and rear pads on the through-electrodes, the through-electrodes penetrating the substrate and protruding to the rear surface;
a step structure comprising a dummy substrate, a buffer layer on the dummy substrate, and a cavity penetrating the dummy substrate and the buffer layer, with the semiconductor chip in the cavity; and
a dielectric layer on at least portions of the semiconductor chip and the step structure, and around the through-electrodes and the rear pads on the rear surface of the substrate,
wherein the substrate and the dummy substrate comprise a first material, and
wherein the buffer layer comprises a second material different from the first material.

19. The semiconductor package of claim 18,
wherein the first material comprises a semiconductor material, and
wherein the second material comprises at least one of an oxide or a nitride of the semiconductor material.

20. A semiconductor package, comprising:
a semiconductor chip comprising a substrate comprising a front surface opposite to a rear surface, front pads on the front surface, through-electrodes electrically connected to the front pads, and rear pads on the through-electrodes, the through-electrodes penetrating the substrate and protruding to the rear surface;
a step structure around the semiconductor chip and comprising a lower surface opposite to an upper surface;
a gap-fill dielectric layer on the rear surface of the semiconductor chip, and the upper surface of the step structure;
a bonding dielectric layer on the gap-fill dielectric layer and on at least portions of the rear pads; and
a top semiconductor chip on the semiconductor chip, and comprising connection pads in contact with the rear pads, and a bonding insulating layer on at least portions of the connection pads and in contact with the bonding dielectric layer,
wherein an upper surface of the gap-fill dielectric layer and upper ends of the through-electrodes provide a flat surface with the bonding dielectric layer and the rear pads on the flat surface, and
wherein the step structure comprises a buffer layer adjacent to the flat surface.
